(19) United States
(12) Patent Application Publication
(10) Pub. No.: US 2026/0165139 A1
(43) Pub. Date: Jun. 11, 2026

(54) SEMICONDUCTOR PACKAGE AND METHOD FOR MANUFACTURING THE SAME

(71) Applicant: Samsung Electronics Co., Ltd., Suwon-si (KR)

(72) Inventor: Sanghyeon JEONG, Suwon-si (KR)

(73) Assignee: Samsung Electronics Co., Ltd., Suwon-si (KR)

(21) Appl. No.: 19/238,976

(22) Filed: Jun. 16, 2025

(30) Foreign Application Priority Data
Dec. 5, 2024 (KR) 10-2024-0179785

(51) Int. Cl. H01L 23/00; H01L 21/56; H01L 23/31; H01L 23/58

(52) U.S. Cl. CPC H10W 42/121; H10W 42/00; H10W 74/014; H10W 74/117; H10W 72/0198

(57) ABSTRACT

Provided is a semiconductor package including a package substrate including an upper surface having a mounting region and a peripheral region surrounding the mounting region, a semiconductor chip on the package substrate in the mounting region, dummy wires on the package substrate in the peripheral region, and a molding layer covering the semiconductor chip and the dummy wires on the package substrate. The dummy wires are arranged along side surfaces of the package substrate, and both ends of each of the dummy wires are connected to the package substrate.

### CROSS-REFERENCE TO RELATED APPLICATIONS

This U.S. non-provisional patent application claims priority under 35 U.S.C. § 119 of Korean Patent Application No. 10-2024-0179785, filed on Dec. 5, 2024, the entire contents of which are hereby incorporated by reference.

### BACKGROUND

The present disclosure herein relates to semiconductor packages and methods for manufacturing the same, and more particularly, to semiconductor packages including a dummy wire and methods for manufacturing the same.

An integrated circuit chip may be packaged into a semiconductor package to have a suitable form to be installed in an electronic device. In general, in a semiconductor package, a semiconductor chip may be mounted on a substrate such as a printed circuit board (PCB), and the semiconductor chip and the PCB may be electrically connected to each other using bonding wires or bumps.

In a semiconductor chip manufacturing process, a plurality of semiconductor packages are typically manufactured by mounting a plurality of semiconductor chips on a single substrate for the improvement of a process yield, forming a molding material covering the semiconductor chips on a package substrate, and then cutting a resultant structure. The semiconductor packages may be formed by performing a sawing process to individually separate the plurality of semiconductor packages formed on the package substrate.

### SUMMARY

The present disclosure provides semiconductor packages with improved structural stability and methods for manufacturing the same.

The present disclosure also provides semiconductor packages with improved heat dissipation efficiency and methods for manufacturing the same.

The present disclosure also provides methods for manufacturing a semiconductor package with a low occurrence rate of defect and semiconductor packages manufactured using the method.

Some example embodiments of the inventive concepts provide a semiconductor package including a package substrate including an upper surface having a mounting region and a peripheral region surrounding the mounting region; a semiconductor chip on the package substrate in the mounting region; dummy wires on the package substrate in the peripheral region; and a molding layer covering the semiconductor chip and the dummy wires on the package substrate. The dummy wires may be arranged along side surfaces of the package substrate. Both ends of each of the dummy wires may be connected to the package substrate.

In some example embodiments of the inventive concepts, a semiconductor package includes a package substrate including an upper surface having a mounting region and a peripheral region surrounding the mounting region; a semiconductor chip on the package substrate in the mounting region; a dummy wire on the package substrate in the peripheral region; and a molding layer covering the semiconductor chip and the dummy wire on the package substrate. The package substrate may include a first pad and a second pad provided on the upper surface of the package substrate and arranged along a first side surface of the package substrate in the peripheral region. The dummy wire may include a first bonding part connected to the first pad; a second bonding part connected to the second pad; and a wire loop connecting the first bonding part and the second bonding part. The molding layer may include a first portion between the dummy wire and the first side surface of the package substrate; and a second portion spaced apart from the first side surface of the package substrate due to the first portion. The first portion and the second portion may be formed of a same material. The first portion and the second portion may have different colors.

In some example embodiments of the inventive concepts, a method for manufacturing a semiconductor package includes providing a package substrate, an upper surface of the package substrate including a plurality of mounting regions spaced apart from each other in a first direction and a scribe lane region between the plurality of mounting regions; mounting a plurality of semiconductor chips on the package substrate in the mounting regions; forming a plurality of dummy wires on the package substrate in the scribe lane region, both ends of each of the dummy wires connected to the package substrate; forming, on the package substrate, a molding layer covering the semiconductor chips and the dummy wires; and cutting the molding layer and the package substrate along a sawing line in the scribe lane region. The dummy wires may be arranged in rows spaced apart from each other in the first direction and extending in a second direction traversing between the mounting regions. The sawing line may extend in the second direction between the rows of the dummy wires. The cutting of the molding layer and the package substrate may include a laser sawing process.

In some example embodiments of the inventive concepts, a semiconductor package may include a package substrate including a mounting region and a peripheral region surrounding the mounting region, a semiconductor chip on the package substrate in the mounting region, dummy wires in the peripheral region, the dummy wires arranged along at least two side surfaces of the package substrate, and a molding layer covering the semiconductor chip and the dummy wires, the dummy wires arranged parallel to and along at least two side surfaces of the semiconductor chip.

In some example embodiments of the inventive concepts, the semiconductor package may include a wire loop of each of the dummy wires may overlap another wire loop of another one of the dummy wires.

### BRIEF DESCRIPTION OF THE FIGURES

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the drawings:

FIGS. 1 and 2 are cross-sectional views for describing a semiconductor package according to some example embodiments of the inventive concepts;

FIG. 3 is a plan view for describing a semiconductor package according to some example embodiments of the inventive concepts;

FIGS. 4 and 5 are cross-sectional views for describing a semiconductor package according to some example embodiments of the inventive concepts;

FIGS. 6 and 7 are plan views for describing a semiconductor package according to some example embodiments of the inventive concepts;

FIG. 8 is a cross-sectional view for describing a semiconductor package according to some example embodiments of the inventive concepts;

FIG. 9 is a plan view for describing a semiconductor package according to some example embodiments of the inventive concepts; and

FIGS. 10A, 10B, 10C, 11A, 11B, 11C, 12A, 12B, 12C, 13A, 13B, and 13C are diagrams for describing a method for manufacturing a semiconductor package according to some example embodiments of the inventive concepts.

### DETAILED DESCRIPTION

A semiconductor package according to the inventive concepts will be described with reference to the drawings.

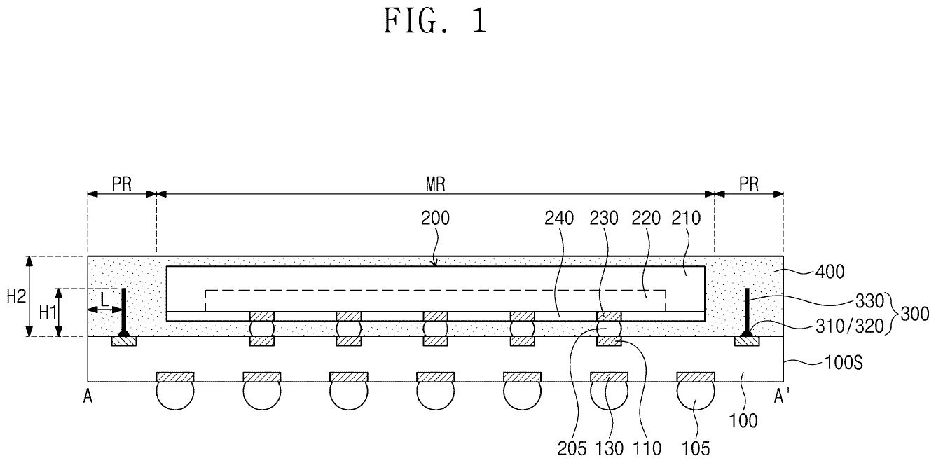

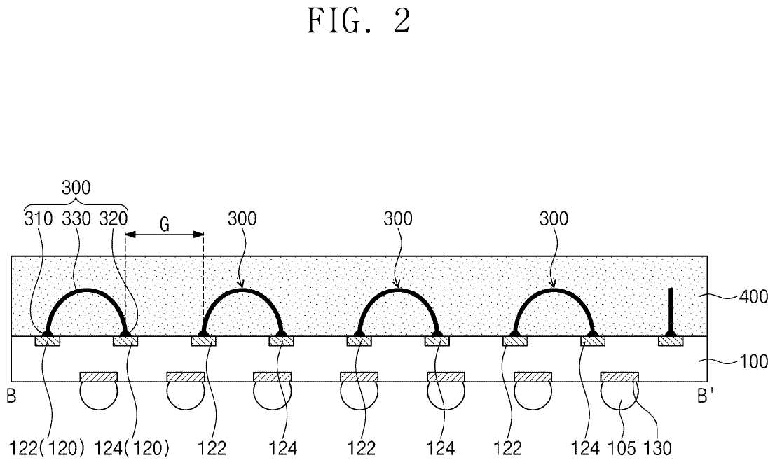

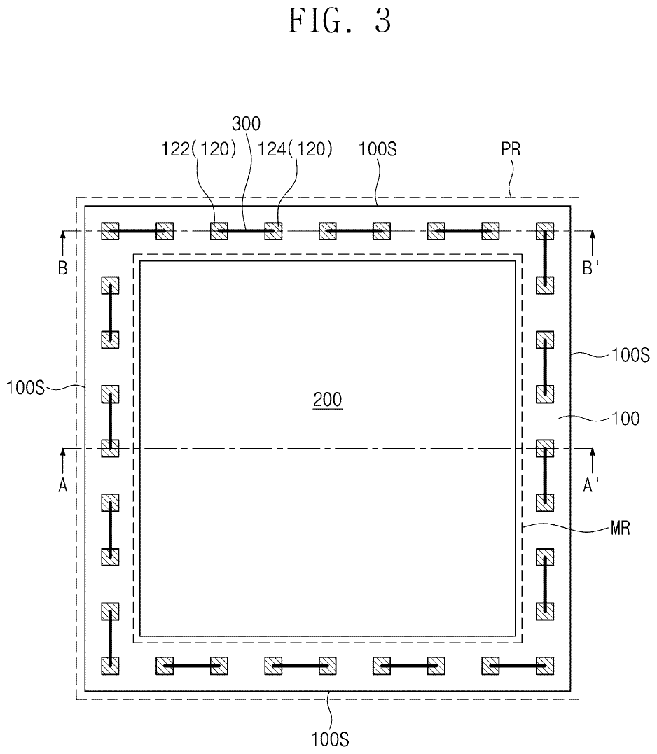

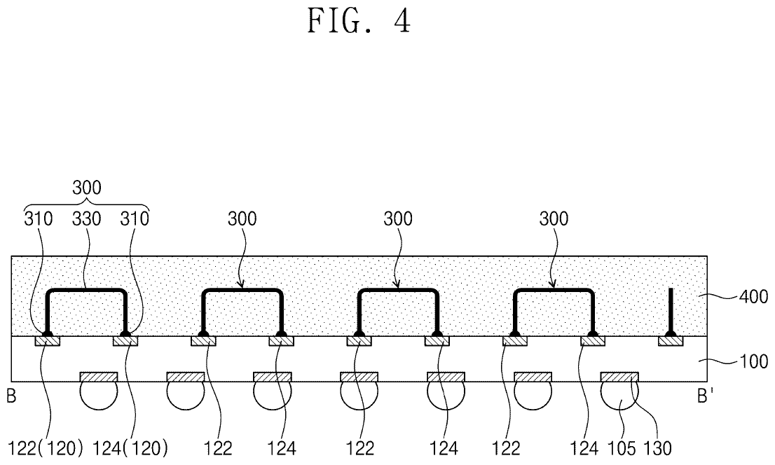

FIGS. 1 and 2 are cross-sectional views for describing a semiconductor package according to some example embodiments of the inventive concepts. FIG. 3 is a plan view for describing a semiconductor package according to some example embodiments of the inventive concepts. FIG. 4 is a cross-sectional view for describing a semiconductor package according to some example embodiments of the inventive concepts. FIG. 1 corresponds to a cross-section taken along line A-A′ of FIG. 3. FIGS. 2 and 4 correspond to a cross-section taken along line B-B′ of FIG. 3.

Referring to FIGS. 1 to 3, a package substrate 100 may be provided. The package substrate 100 may be a printed circuit board (PCB) with a signal pattern provided on an upper surface of the package substrate 100. The package substrate 100 may have a structure including a core pattern and wiring layers stacked on each of an upper surface and lower surface of the core pattern.

According to some example embodiments, the package substrate 100 may be a redistribution substrate. For example, the package substrate 100 may include two or more substrate wiring layers stacked on each other. In the present disclosure, a substrate wiring layer may refer to a wiring layer formed by patterning each of one insulating material layer and one conductive material layer. That is, conductive patterns in one substrate wiring layer may be lines extending horizontally and may not vertically overlap each other. Each of the substrate wiring layers may include substrate insulating patterns and substrate wiring patterns in the substrate insulating patterns. The substrate wiring patterns in any one of the substrate wiring layers may be electrically connected to the substrate wiring patterns of another adjacent substrate wiring layer.

The upper surface of the package substrate 100 may have a mounting region MR and a peripheral region PR. The mounting region MR may be a region for mounting a semiconductor chip 200 that will be described layer. The mounting region MR may be located on a center of the upper surface of the package substrate 100. The peripheral region PR may be an edge of the upper surface of the package substrate 100 other than the mounting region MR. The semiconductor chip 200 may not be provided in the peripheral region PR. The peripheral region PR may be in contact with side surfaces 100s of the package substrate 100. The peripheral region PR may extend along the side surfaces 100s of the package substrate 100. In other words, the peripheral region PR may surround the mounting region MR. The mounting region MR may be spaced apart from the side surfaces 100s of the package substrate 100 due to the peripheral region PR. Although FIG. 3 illustrates the mounting region MR as having a quadrilateral shape, example embodiments of the inventive concepts are not limited thereto. The mounting region MR may be provided in various shapes according to a planar shape of the package substrate 100 or a planar shape (e.g., a triangular shape, a hexagon shape, and/or a circular shape) of the semiconductor chip 200.

The package substrate 100 may have a plurality of first upper substrate pads 110 and a plurality of second upper substrate pads 120 provided on the upper surface of the package substrate 100.

The first upper substrate pads 110 may be arranged in the mounting region MR. The first upper substrate pads 110 may be electrically connected to lines in the package substrate 100, for example, the signal pattern, the core pattern, the wiring layers, or the substrate wiring patterns.

The second upper substrate pads 120 may be arranged in the peripheral region PR. The second upper substrate pads 120 may be arranged adjacent to the side surfaces 100s of the package substrate 100. The second upper substrate pads 120 may be arranged along the side surfaces 100s of the package substrate 100. The second upper substrate pads 120 may surround the mounting region MR. The second upper substrate pads 120 may be electrically insulated from the lines in the package substrate 100. The second upper substrate pads 120 may be floated in the package substrate 100. However, example embodiments of the inventive concepts are not limited thereto, and the second upper substrate pads 120 may be electrically connected to the lines in the package substrate 100.

Although FIGS. 1 and 2 illustrate upper surfaces of the first upper substrate pads 110 and upper surfaces of the second upper substrate pads 120 as being coplanar with the upper surface of the package substrate 100, example embodiments of the inventive concepts are not limited thereto. According to some example embodiments, the first upper substrate pads 110 and the second upper substrate pads 120 may protrude above the upper surface of the package substrate 100.

The package substrate 100 may have a plurality of lower substrate pads 130 provided to a lower surface of the package substrate 100. The lower substrate pads 130 may be electrically connected to the first upper substrate pads 110 through the lines in the package substrate 100.

A plurality of external terminals 105 may be provided on the lower surface of the package substrate 100. The external terminals 105 may be arranged on the lower substrate pads 130. The external terminals 105 may include a solder ball, a solder bump, or a solder pad. The package substrate 100 may have a form of a ball grid array (BGA), a fine ball-grid array (FBGA), or a land grid array (LGA) according to the type of the external terminals 105.

The semiconductor chip 200 may be disposed on the package substrate 100. The semiconductor chip 200 may include, for example, a semiconductor substrate 210, a circuit layer 220, chip pads 230, and a chip passivation layer 240.

The semiconductor substrate 210 may be provided. The semiconductor substrate 210 may include a semiconductor material.

The circuit layer 220 may be provided to a lower surface of the semiconductor substrate 210. The circuit layer 220 may include a semiconductor element and a wiring part connected to the semiconductor element. For example, the semiconductor element may include transistors provided to the lower surface of the semiconductor substrate 210. The wiring part may be disposed on the lower surface of the semiconductor substrate 210 and electrically connected to the transistors.

The plurality of chip pads 230 may be arranged on the lower surface of the semiconductor substrate 210. The chip pads 230 may be electrically connected to the circuit layer 220, for example, the transistors.

The chip passivation layer 240 may be disposed on the lower surface of the semiconductor substrate 210. The chip passivation layer 240 may cover the circuit layer 220 on the lower surface of the semiconductor substrate 210. The chip passivation layer 240 may surround the chip pads 230 on the lower surface of the semiconductor substrate 210. The chip pads 230 may be exposed by the chip passivation layer 240. For example, in a plan view, the chip passivation layer 240 may surround the chip pads 230 but may not cover the chip pads 230. A lower surface of the chip passivation layer 240 may be coplanar with lower surfaces of the chip pads 230.

The above-mentioned configuration of the semiconductor chip 200 is merely an example of the semiconductor chip 200, and example embodiments of the inventive concepts are not limited thereto. The semiconductor chip 200 may be provided as various types of chips, devices, or elements as desired.

The semiconductor chip 200 may be disposed on the package substrate 100. The semiconductor chip 200 may be arranged in the mounting region MR. In a plan view, the semiconductor chip 200 may be spaced apart from the peripheral region PR. The semiconductor chip 200 may be disposed face-down on the package substrate 100. For example, the chip pads 230 of the semiconductor chip 200 may face the package substrate 100.

The semiconductor chip 200 may be mounted on the package substrate 100. For example, the semiconductor chip 200 may be mounted on the package substrate 100 in a flip chip manner. A plurality of chip terminals 205 may be provided on the chip pads 230 of the semiconductor chip 200. The chip terminals 205 may connect the chip pads 230 of the semiconductor chip 200 to the first upper substrate pads 110 of the package substrate 100. According to some example embodiments, the semiconductor chip 200 may be mounted on the package substrate 100 in a wire bonding manner.

Although not illustrated, an under-fill layer may be provided between the semiconductor chip 200 and the package substrate 100. The under-fill layer may fill a space between the semiconductor chip 200 and the package substrate 100 and surround the chip terminals 205. In the case where the semiconductor chip 200 is mounted on the package substrate 100 in a wire bonding manner, an adhesive layer may be provided between the semiconductor chip 200 and the package substrate 100. The adhesive layer may bond the semiconductor chip 200 to the upper surface of the package substrate 100.

A plurality of dummy wires 300 may be provided on the package substrate 100. The dummy wires 300 may be arranged in the peripheral region PR. The dummy wires 300 may be arranged adjacent to the side surfaces 100s of the package substrate 100. The dummy wires 300 may be arranged along the side surfaces 100s of the package substrate 100. The dummy wires 300 may surround the peripheral region MR.

The dummy wires 300 may each be a bonding wire. Both ends of each of the dummy wires 300 may be connected to the package substrate 100. The dummy wires 300 may be electrically insulated from the first upper substrate pads 110 and the semiconductor chip 200. However, example embodiments of the inventive concepts are not limited thereto, and the dummy wires 300 may be electrically connected to the first upper substrate pads 110, the semiconductor chip 200, and the external terminals 105. The dummy wires 300 may be connected to the second upper substrate pads 120 of the package substrate 100. In more detail, both ends of each of the dummy wires 300 may be respectively connected to two adjacent pads among the second upper substrate pads 120. Hereinafter, for convenience, two second upper substrate pads 120 connected to one dummy wire 300 will be individually referred to as a first sub pad 122 and a second sub pad 124. However, this is only for ease in description and does not indicate that the first sub pad 122 and the second sub pad 124 are different from each other. Hereinafter, descriptions will be continuously provided with respect to one dummy wire 300.

The dummy wire 300 may be bonded to the first sub pad 122 and the second sub pad 124 in a stitch bonding manner and/or ball bonding manner. For example, the dummy wire 300 may include a first bonding part 310 connected to the first sub pad 122, a second bonding part 320 connected to the second sub pad 124, and a wire loop 330 connecting the first bonding part 310 and the second bonding part 320. The first bonding part 310 and the second bonding part 320 may have a ball shape or a folding shape. A width of the first bonding part 310 and a width of the second bonding part 320 may be larger than a width of the wire loop 330. As illustrated in FIG. 2, a side shape of the wire loop 330 may be a semicircle. Here, the side shape of the wire loop 330 represents a shape of the wire loop 330 as viewed from the side surface 100s of the package substrate 100. In other words, the side shape of the wire loop 330 represents a shape defined by the dummy wire 300 and the package substrate 100 as viewed from the side surface. Furthermore, the side surface 100s of the package substrate 100 represents the side surface 100s adjacent to the dummy wire 300 being described among the side surfaces 100s of the package substrate 100. According to some example embodiments, as illustrated in FIG. 4, the side shape of the wire loop 330 may be quadrilateral. However, example embodiments of the inventive concepts are not limited thereto, and the side shape of the wire loop 330 may be varied as desired, for example, a semicircular shape. In a plan view, the dummy wire 300 may extend in a parallel direction to the side surface 100s of the package substrate 100. In other words, the first sub pad 122 and the second sub pad 124 may be arranged spaced apart from each other in a parallel direction to the side surface 100s of the package substrate 100, and the dummy wire 300 may extend from the first sub pad 122 to the second sub pad 124. A distance L between the dummy wire 300 and the side surface 100s of the package substrate 100 may be about or exactly 20 micrometers to about or exactly 100 micrometers.

The dummy wires 300 may be arranged along the side surfaces 100s of the package substrate 100. The second upper substrate pads 120 may include the first sub pads 122 and the second sub pads 124. The first sub pads 122 and the second sub pads 124 may be arranged along the side surfaces 100s of the package substrate 100 and may be alternately arranged with each other. In other words, the first sub pads 122 and the second sub pads 124 may be arranged along a virtual quadrilateral ring surrounding the mounting region MR. The dummy wires 300 may each be connected to the first sub pad 122 and the second sub pad 124 that are adjacent to each other among the first sub pads 122 and the second sub pads 124. A distance G between the dummy wires 300 adjacent to each other may be about or exactly 50 micrometers to about or exactly 200 micrometers.

A molding layer 400 may be provided on the package substrate 100. The molding layer 400 may cover the semiconductor chip 200 and the dummy wires 300 on the upper surface of the package substrate 100. An uppermost end of the dummy wires 300, i.e., an uppermost end of the wire loop 330 of the dummy wires 300, may be spaced apart from an upper surface of the molding layer 400. A height H1 of the dummy wire 300 may be about or exactly 0.3 to about or exactly 0.8 times a height H2 of the molding layer 400 that will be described later. Here, the height H1 of the dummy wire 300 may be a vertical distance from the upper surface of the package substrate 100, more specifically, the upper surface of the second upper substrate pads 120, to the uppermost end of the dummy wires 300. The height H2 of the molding layer 400 may be a vertical distance from the upper surface of the package substrate 100 to the upper surface of the molding layer 400. The molding layer 400 may include an insulative polymer material such as an epoxy molding compound (EMC).

According to some example embodiments of the inventive concepts, the dummy wires 300 may be arranged in the peripheral region PR surrounding the semiconductor chip 200. The dummy wires 300 may surround the semiconductor chip 200. The dummy wires 300 may be provided to protect the semiconductor chip 200 from an external stress. The dummy wires 300 may be resistant to a mechanical stress. For example, when an impact or stress is applied from one side of the semiconductor package to the semiconductor chip 200, the dummy wires 300 may function as a partition wall that mitigates the impact or stress, and may protect the semiconductor chip 200 from the impact or stress. For example, the impact or stress may pass through the molding layer 400 and may be distributed to the dummy wires 300. That is, a semiconductor package having improved structural stability may be provided.

Furthermore, since the dummy wires 300 are provided as metal, the dummy wires 300 may have high thermal conductivity. Therefore, heat generated in the semiconductor chip 200 or externally applied heat may be delivered to the package substrate 100 through the dummy wires 300 and may be dissipated downward from the package substrate 100. That is, a semiconductor package having higher heat dissipation efficiency may be provided.

One dummy wire 300 may be connected to a pair of the second upper substrate pads 120. That is, one second upper substrate pad 120 may be connected to one dummy wire 300. The number of the second upper substrate pads 120 may be two times the number of the dummy wires 300.

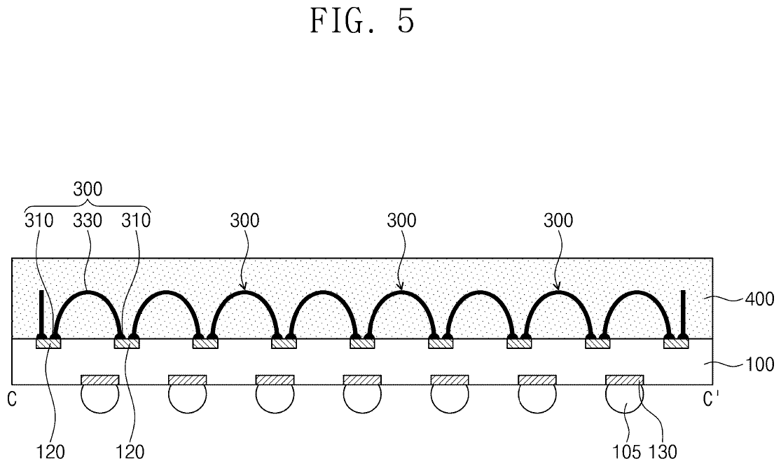

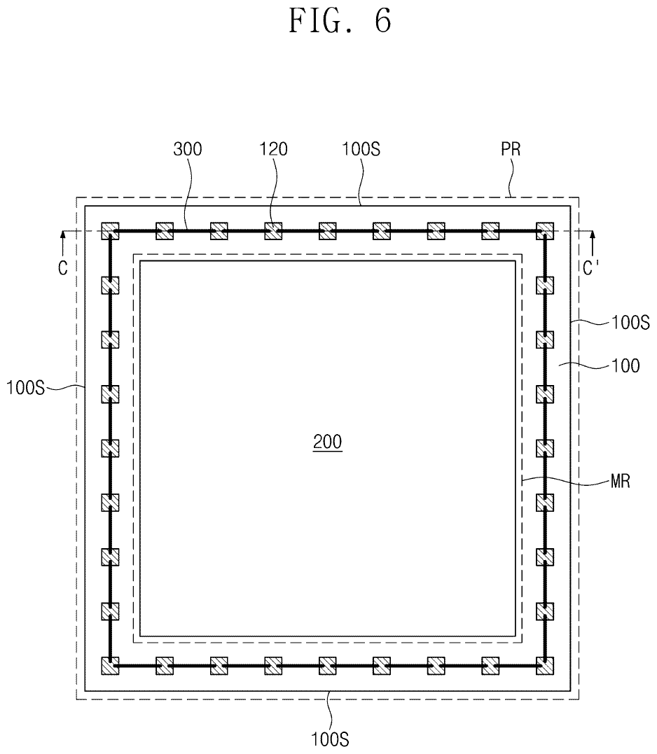

FIG. 5 is a cross-sectional view for describing a semiconductor package according to some example embodiments of the inventive concepts. FIG. 6 is a plan view for describing a semiconductor package according to some example embodiments of the inventive concepts. FIG. 5 corresponds to a cross-section taken along line C-C′ of FIG. 6.

Referring to FIGS. 1, 5, and 6, the plurality of dummy wires 300 may be provided on the package substrate 100. The dummy wires 300 may be arranged in the peripheral region PR. The dummy wires 300 may be arranged adjacent to the side surfaces 100s of the package substrate 100. The dummy wires 300 may be arranged along the side surfaces 100s of the package substrate 100. The dummy wires 300 may surround the peripheral region MR.

The dummy wires 300 may be connected to the plurality of second upper substrate pads 120 of the package substrate 100. The dummy wires 300 may each connect two second upper substrate pads 120 adjacent to each other. Two dummy wires 300 may be connected to one second upper substrate pad 120. The number of the second upper substrate pads 120 may be equal to the number of the dummy wires 300.

According to some example embodiments of the inventive concepts, a larger number of dummy wires 300 may be arranged in the peripheral region PR surrounding the semiconductor chip 200. When an impact or stress is applied from one side of the semiconductor package to the semiconductor chip 200, the dummy wires 300 may function as a partition wall that mitigates the impact or stress, and the larger number of the dummy wires 300 may prevent or reduce damage to the semiconductor chip 200 from the impact or stress. That is, a semiconductor package having additionally improved structural stability may be provided.

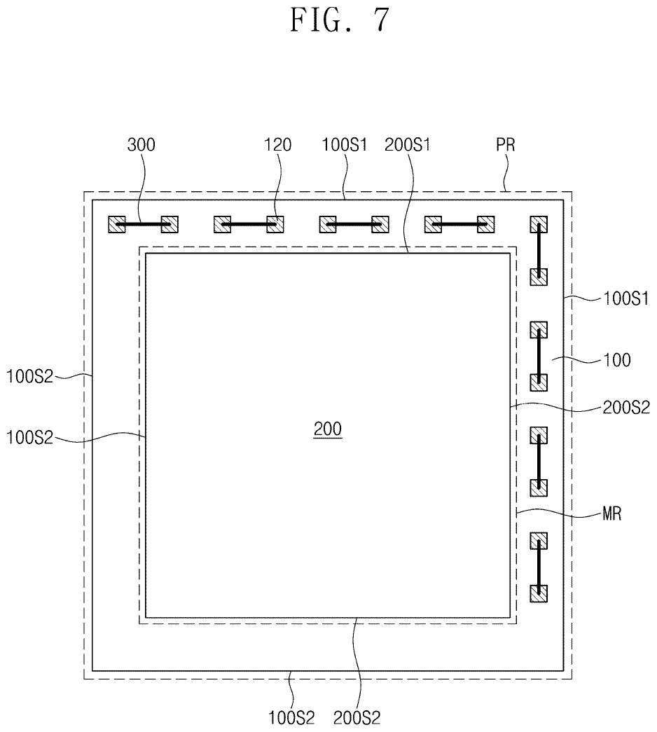

FIG. 7 is a plan view for describing a semiconductor package according to some example embodiments of the inventive concepts.

Referring to FIG. 7, the plurality of dummy wires 300 may be provided on the package substrate 100. The dummy wires 300 may be arranged in the peripheral region PR. The dummy wires 300 may be arranged adjacent to two first side surfaces 100s1 adjacent to each other among the side surfaces of the package substrate 100. In other words, the dummy wires 300 may be arranged on two third side surfaces 200s1 adjacent to each other among side surfaces of the semiconductor chip 200. The dummy wires 300 may not be arranged adjacent to two other second side surfaces 100s2 adjacent to each other among the side surfaces of the package substrate 100. In other words, the dummy wires 300 may not be arranged on two other fourth side surfaces 200s2 adjacent to each other among the side surfaces of the semiconductor chip 200.

The dummy wires 300 may be arranged along the first side surfaces 100s1 of the package substrate 100. The second upper substrate pads 120 may be arranged along the first side surfaces 100s1 of the package substrate 100. The dummy wires 300 may be connected to the second upper substrate pads 120.

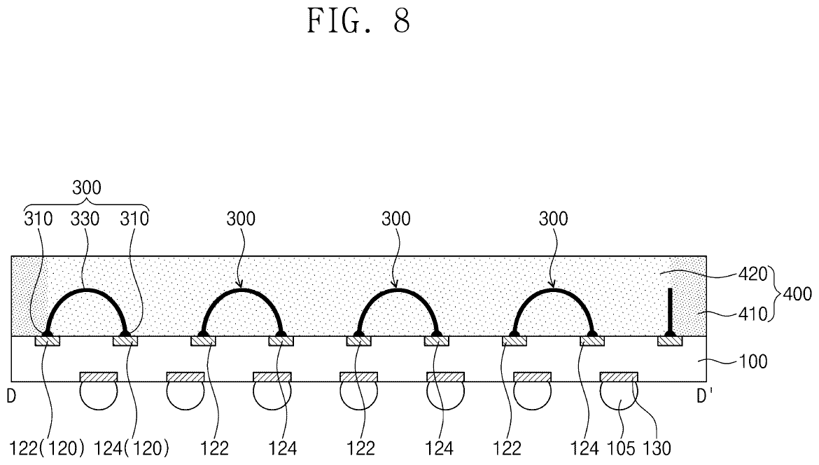

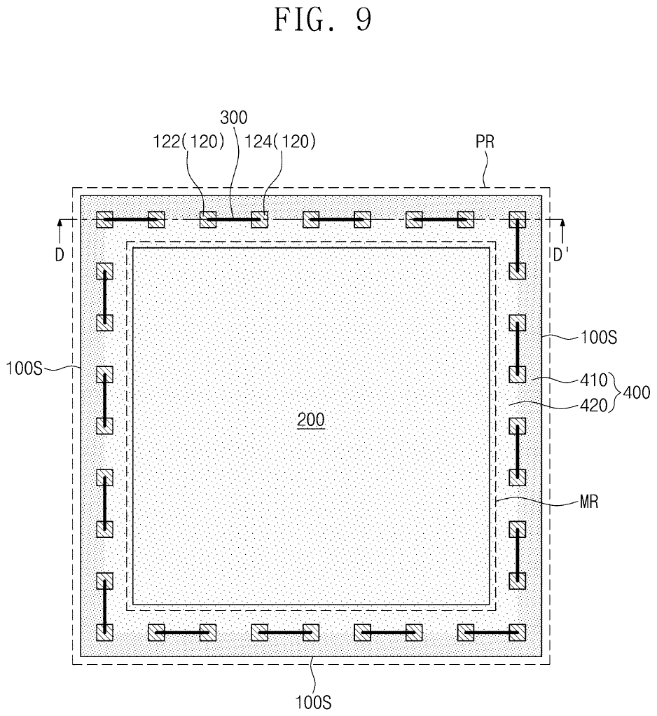

FIG. 8 is a cross-sectional view for describing a semiconductor package according to some example embodiments of the inventive concepts. FIG. 9 is a plan view for describing a semiconductor package according to some example embodiments of the inventive concepts.

Referring to FIGS. 8 and 9, the molding layer 400 may have a first portion 410 and a second portion 420. The first portion 410 may be a portion of the molding layer 400 adjacent to the side surfaces 100s of the package substrate 100. The first portion 410 may be located in the peripheral region PR. The first portion 410 may be located between the plurality of dummy wires 300 and the side surfaces 100s of the package substrate 100. In a plan view, the first portion 410 may surround the second portion 420. The second portion 420 may be located in the mounting region MR. The second portion 420 may be spaced apart from the side surfaces 100s of the package substrate 100 due to the first portion 410.

The first portion 410 and the second portion 420 may include the same material. For example, the first portion 410 and the second portion 420 may include an epoxy molding compound (EMC). The first portion 410 and the second portion 420 may have different physical properties. For example, the first portion 410 and the second portion 420 may have different colors. Alternatively, for example, the first portion 410 and the second portion 420 may include materials which are the same but have different molecular structures.

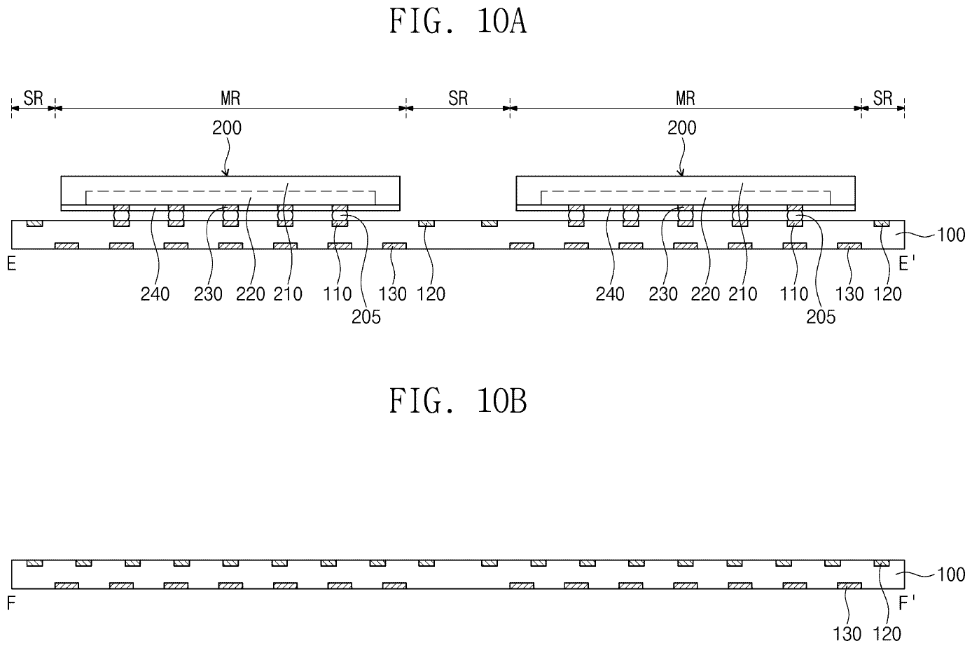

FIGS. 10A, 10B, 10C, 11A, 11B, 11C, 12A, 12B, 12C, 13A, 13B, and 13C are diagrams for describing a method for manufacturing a semiconductor package according to some example embodiments of the inventive concepts. FIGS. 10A, 11A, 12A, and 13A correspond to cross-sections taken along line E-E′ of FIGS. 10C, 11C, 12C, and 13C, respectively. FIGS. 10B, 11B, 12B, and 13B correspond to cross-sections taken along line F-F′ of FIGS. 10C, 11C, 12C, and 13C, respectively.

Referring to FIGS. 10A, 10B, and 10C, the package substrate 100 may be provided. The package substrate 100 may have a plurality of regions in which semiconductor chips are mounted. For example, the package substrate 100 may have a plurality of mounting regions MR. The package substrate 100 may be divided and spaced apart from each other having therebetween a scribe lane region SR in which a sawing process is performed in a process described below. That is, the scribe lane region SR may define the mounting regions MR in which the semiconductor chips are mounted on the package substrate 100. The package substrate 100 may be a printed circuit board (PCB) with a signal pattern provided on an upper surface of the package substrate 100. The package substrate 100 may have the first upper substrate pads 110 located in the mounting regions MR and the second upper substrate pads 120 located in the scribe lane region SR.

A plurality of semiconductor chips 200 may be mounted on the package substrate 100. The semiconductor chips 200 may be the semiconductor chip 200 described above with reference to FIGS. 1 to 9. The semiconductor chips 200 may be mounted in the mounting regions MR, respectively, on the package substrate 100. The semiconductor chips 200 may be mounted in a flip chip manner. For example, the chip terminals 205 may be provided on the chip pads 230 of the semiconductor chips 200. The semiconductor chips 200 may be arranged on the package substrate 100 so that the chip terminals 205 may be aligned with the first upper substrate pads 110. The semiconductor chips 200 may be lowered so that the chip terminals 205 may be in contact with the first upper substrate pads 110. Thereafter, a reflow process may be performed on the chip terminals 205. The chip terminals 205 may connect the chip pads 230 and the first upper substrate pads 110.

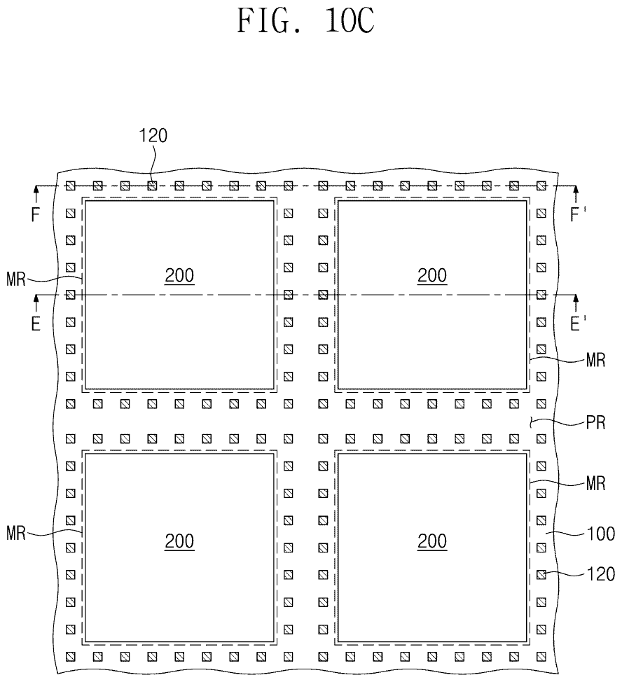

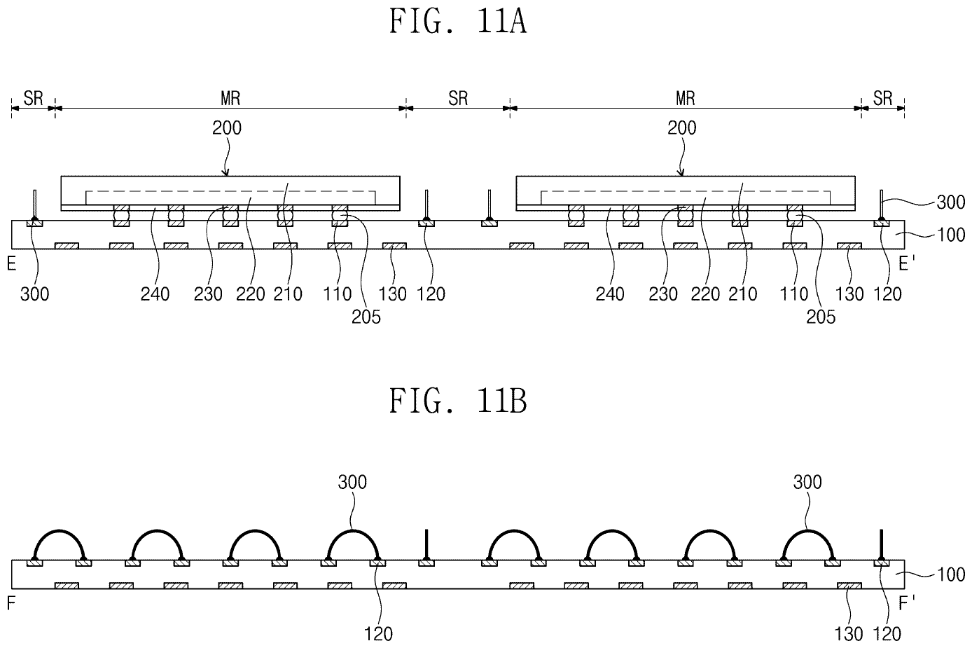

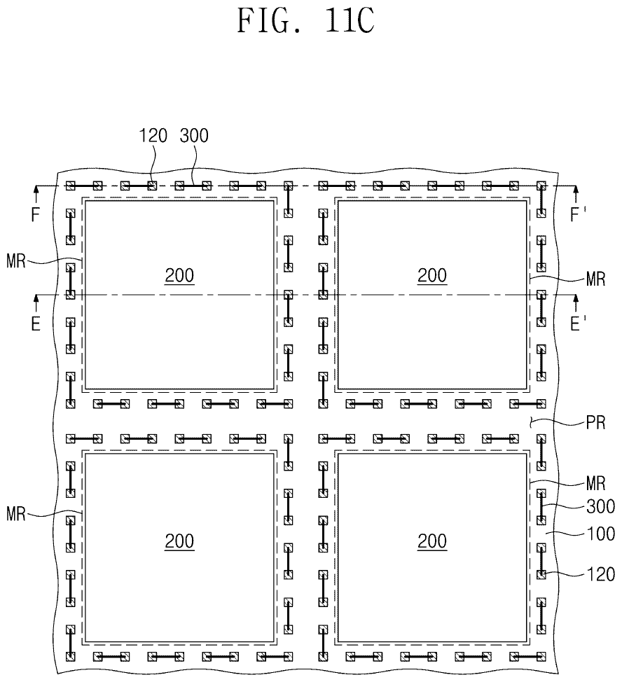

Referring to FIGS. 11A, 11B, and 11C, a plurality of dummy wires 300 may be formed in the scribe lane region SR. The dummy wires 300 may be formed on the second upper substrate pads 120. The dummy wires 300 may connect two second upper substrate pads 120 adjacent to each other. The dummy wires 300 may be formed through a metal wire bonding process, for example. The metal wire bonding process may include, for example, coupling a metal wire to a bonding device, for example, a capillary, positioning the capillary on one of the plurality of second upper substrate pads 120, lowering the capillary and attaching the first bonding part 310 (see FIG. 2) of the metal wire to the one of the second upper substrate pads 120, raising the capillary and pulling the metal wire from the first bonding part 310 to form the wire loop 330 (see FIG. 2), positioning the capillary on another adjacent one of the second upper substrate pads 120, and lowering the capillary and attaching the second bonding part 320 (see FIG. 2) of the metal wire to the other one of the second upper substrate pads 120.

In a plan view, one mounting region MR may be surrounded by one group formed by the plurality of dummy wires 300. In other words, each group including the dummy wires 300 may surround one mounting region MR. In a cross-sectional view, when the mounting regions MR are spaced apart from each other in a first direction, the dummy wires 300 may be arranged along two rows extending in a second direction perpendicular to the first direction. The rows of the dummy wires 300 may be spaced apart from each other in the first direction. When the mounting regions MR are two-dimensionally arranged along the first direction and the second direction, the dummy wires 300 may be arranged along quadrilateral lines surrounding the mounting regions MR.

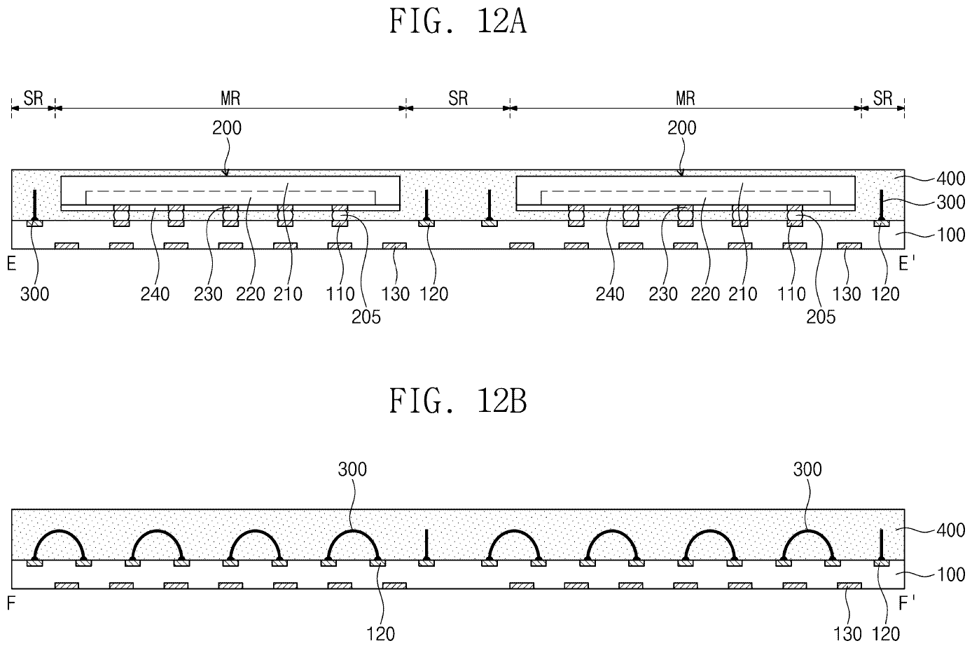

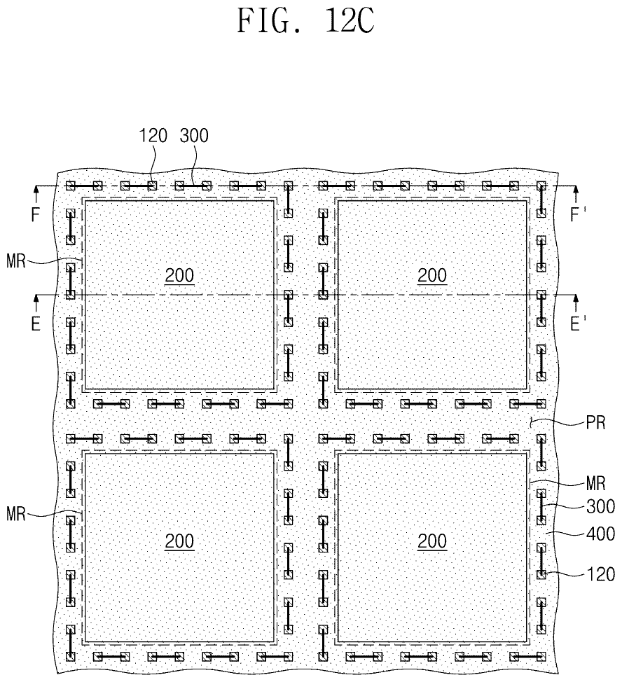

Referring to FIGS. 12A, 12B, and 12C, the molding layer 400 may be formed on the package substrate 100. For example, a molding material may be applied onto the upper surface of the package substrate 100 so as to bury the semiconductor chips 200 and the dummy wires 300, and the molding material may be cured, thus forming the molding layer 400. For example, the molding material may be an epoxy molding compound (EMC).

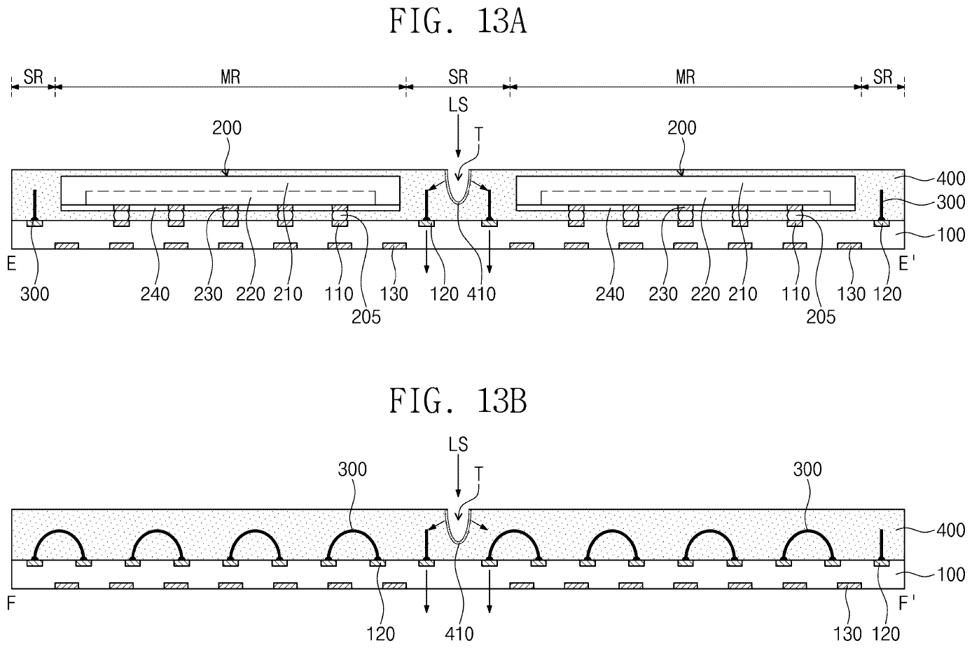

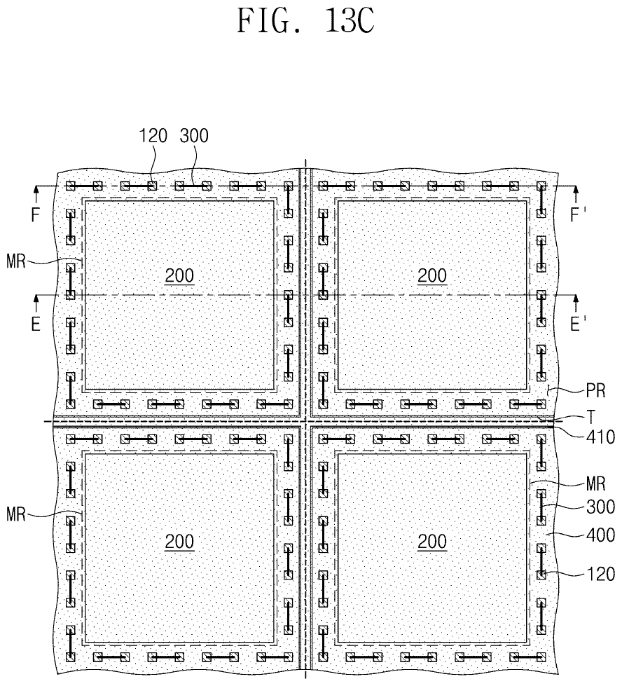

Referring to FIGS. 13A, 13B, and 13C, a singulation process may be performed. For example, a cutting process may be performed along sawing lines on the package substrate 100 and the molding layer 400 so that a plurality of semiconductor packages may be separated from each other. The sawing lines may be virtual lines in the scribe lane region SR. The sawing lines may traverse between the mounting regions MR as indicated by a dashed line in FIG. 13C. For example, when the mounting regions MR are spaced apart from each other in the first direction, the sawing lines may extend in the second direction perpendicular to the first direction between the mounting regions MR. The sawing lines may extend in the second direction between the rows of the dummy wires 300 spaced apart in the first direction in the scribe lane region SR. When the mounting regions MR are two-dimensionally arranged along the first direction and the second direction, the sawing lines may have a lattice shape or a shape of #(or hash sign) extending along the first direction and the second direction between the mounting regions MR.

The molding layer 400 and the package substrate 100 may be sequentially cut through the cutting process. As the cutting process is performed, a trench T may be formed in the molding layer 400 (e.g., the molding layer 400 may define the trench T). As the cutting process progresses, the trench T may become deeper, and, as a result, the molding layer 400 and the package substrate 100 may be completely penetrated by the trench T. That is, the molding layer 400 and the package substrate 100 may be cut. The trench T may be formed along the sawing lines.

The cutting process may be performed through a laser sawing process. For example, the upper surface of the molding layer 400 may be irradiated with a laser beam. A portion 410 of the molding layer 400 may be heated due to the irradiation of the laser beam. The portion 410 of the molding layer 400 may be a portion of the molding layer 400 that is in contact with the trench T. A physical property or color of the portion 410 of the molding layer 400 may change due to the laser beam.

According to some example embodiments of the inventive concepts, the portion 410 of the molding layer 400 may change in property or in color due to the laser beam used in the laser sawing process. The dummy wires 300 may be provided adjacent to the sawing lines. As indicated by an arrow in FIGS. 13A and 13B, heat generated due to the laser beam may be transferred to the dummy wires 300. Since the dummy wires 300 are provided as metal, the dummy wires 300 may have high thermal conductivity. Therefore, the heat generated due to the laser beam may be delivered to the package substrate 100 through the dummy wires 300 and may be dissipated downward from the package substrate 100. The dissipation of the heat generated due to the laser beam may be facilitated, and a change in property or color of the molding layer 400 may reduce. That is, a method for manufacturing a semiconductor package with a low occurrence rate of defect may be provided.

As the laser sawing process continues, the molding layer 400 and the package substrate 100 may be completely cut. Accordingly, semiconductor packages may be separated from each other. The portion 410 of the molding layer 400, which is adjacent to a side surface of the molding layer 400, may include the same material as a remaining portion of the molding layer 400. The portion 410 and the remaining portion of the molding layer 400 may include an epoxy molding compound (EMC). The portion 410 and the remaining portion of the molding layer 400 may have different physical properties. For example, the portion 410 and the remaining portion of the molding layer 400 may have different colors. Alternatively, for example, the portion 410 and the remaining portion of the molding layer 400 may include materials which are the same but have different molecular structures.

Thereafter, the external terminals 105 may be attached to the lower substrate pads 130 of the package substrate 100.

In a semiconductor package according to some example embodiments of the inventive concepts, dummy wires may surround a semiconductor chip. When an impact or stress is applied from one side of the semiconductor package to the semiconductor chip, the dummy wires may function as a partition wall that mitigates the impact or stress, and may protect the semiconductor chip from the impact or stress. That is, a semiconductor package having improved structural stability may be provided.

According to a method for manufacturing a semiconductor package according to some example embodiments of the inventive concepts, a portion of a molding layer may change in property or color due to a laser beam used in a laser sawing process. Dummy wires may be provided adjacent to the sawing line. Heat generated due to the laser beam may be transferred to the dummy wires. Therefore, the heat generated due to the laser beam may be delivered to the package substrate through the dummy wires and may be dissipated downward from the package substrate. The dissipation of the heat generated due to the laser beam may be facilitated, and a change in property or color of the molding layer may reduce. That is, a method for manufacturing a semiconductor package with a low occurrence rate of defect may be provided.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10 %) around the stated numerical values or shapes.

Although embodiments of the inventive concepts have been described with reference to the accompanying drawings, those of ordinary skill in the art could easily understood that the inventive concepts can be carried out in other specific forms without changing the technical concepts or essential features. Therefore, the above example embodiments should be considered illustrative and should not be construed as limiting.

What is claimed is:

1. A semiconductor package comprising:
a package substrate comprising an upper surface having a mounting region and a peripheral region surrounding the mounting region;
a semiconductor chip on the package substrate in the mounting region;
dummy wires on the package substrate in the peripheral region; and
a molding layer covering the semiconductor chip and the dummy wires on the package substrate,
the dummy wires arranged along side surfaces of the package substrate, and
both ends of each of the dummy wires connected to the package substrate.

2. The semiconductor package of claim 1, wherein
the package substrate includes first pads and second pads on the upper surface of the package substrate in the peripheral region,
the first pads and the second pads are arranged along the side surfaces of the package substrate and arranged alternately, and
each of the dummy wires is connected to a respective first pad and a respective second pad that are adjacent to each other among the first pads and the second pads.

3. The semiconductor package of claim 2, wherein each of the dummy wires includes:
a first bonding part connected to the respective first pad;
a second bonding part connected to the respective second pad; and
a wire loop connecting the first bonding part and the second bonding part.

4. The semiconductor package of claim 3, wherein the wire loop of each of the dummy wires has a semicircular shape or quadrilateral shape as viewed from a side.

5. The semiconductor package of claim 1, wherein the dummy wires each extend in a direction parallel to a side surface adjacent to the dummy wires among the side surfaces of the package substrate when viewed in a plane.

6. The semiconductor package of claim 1, wherein a distance between the dummy wires is 50 micrometers to 200 micrometers.

7. The semiconductor package of claim 1, wherein an uppermost end of each of the dummy wires is spaced apart from an upper surface of the molding layer.

8. The semiconductor package of claim 1, wherein a height of the dummy wires is 0.3 to 0.8 times a height of the molding layer.

9. The semiconductor package of claim 1, wherein a distance between the side surfaces of the package substrate and the dummy wires is 20 micrometers to 100 micrometers.

10. The semiconductor package of claim 1, wherein
the molding layer includes:
a first portion located between the dummy wires and the side surfaces of the package substrate; and
a second portion spaced apart from the side surfaces of the package substrate due to the first portion,
the first portion and the second portion are formed of a same material, and
the first portion and the second portion have different colors.

11. A semiconductor package comprising:
a package substrate comprising an upper surface having a mounting region and a peripheral region surrounding the mounting region;
a semiconductor chip on the package substrate in the mounting region;
a dummy wire on the package substrate in the peripheral region; and
a molding layer covering the semiconductor chip and the dummy wire on the package substrate,
the package substrate comprising a first pad and a second pad on the upper surface of the package substrate and arranged along a first side surface of the package substrate in the peripheral region,
the dummy wire comprising
a first bonding part connected to the first pad;
a second bonding part connected to the second pad; and
a wire loop connecting the first bonding part and the second bonding part, and the molding layer includes
a first portion between the dummy wire and the first side surface of the package substrate; and
a second portion spaced apart from the first side surface of the package substrate due to the first portion,
the first portion and the second portion formed of a same material, and
the first portion and the second portion having different colors.

12. The semiconductor package of claim 11, wherein
the dummy wire is provided in plurality, and
the dummy wires are arranged along the first side surface and other side surfaces of the package substrate.

13. The semiconductor package of claim 12, wherein
the first pad is provided in plurality,
the second pad is provided in plurality,
the first pads and the second pads are arranged along the first side surface and the other side surfaces of the package substrate and arranged alternately, and
each of the dummy wires is connected to a respective first pad and a respective second pad that are adjacent to each other among the first pads and the second pads.

14. The semiconductor package of claim 12, wherein a distance between the dummy wires is 50 micrometers to 200 micrometers.

15. The semiconductor package of claim 11, wherein the wire loop has a semicircular shape or quadrilateral shape as viewed from a side.

16. The semiconductor package of claim 11, wherein the dummy wire extends in a direction parallel to the first side surface of the package substrate when viewed in a plane.

17. The semiconductor package of claim 11, wherein a height of the dummy wire is 0.3 to 0.8 times a height of the molding layer.

18. The semiconductor package of claim 11, wherein a distance between the first side surface of the package substrate and the dummy wire is 20 micrometers to 100 micrometers.

19. A method for manufacturing a semiconductor package, the method comprising:
providing a package substrate, an upper surface of the package substrate comprising a plurality of mounting regions spaced apart from each other in a first direction and a scribe lane region between the plurality of mounting regions;
mounting a plurality of semiconductor chips on the package substrate in the mounting regions;
forming a plurality of dummy wires on the package substrate in the scribe lane region, both ends of each of the dummy wires connected to the package substrate;
forming, on the package substrate, a molding layer covering the semiconductor chips and the dummy wires; and
cutting the molding layer and the package substrate along a sawing line in the scribe lane region,
the dummy wires arranged in rows spaced apart from each other in the first direction and extending in a second direction traversing between the mounting regions,
the sawing line extending in the second direction between the rows of the dummy wires, and
the cutting of the molding layer and the package substrate comprising a laser sawing process.

20. The method of claim 19, wherein each of the dummy wires includes:
a first bonding part and a second bonding part spaced apart from each other in the second direction; and
a wire loop connecting the first bonding part and the second bonding part.
